(19) United States
(12) Patent Application Publication
(10) Pub. No.: US 2015/0187725 A1
(43) Pub. Date: Jul. 2, 2015

(54) METHOD OF JOINING SILVER PASTE

(71) Applicant: Hyundai Motor Company, Seoul (KR)

(72) Inventors: Kyoung-Kook Hong, Hwaseong (KR); Su Bin Kang, Busan (KR)

(21) Appl. No.: 14/444,566

(22) Filed: Jul. 28, 2014

(30) Foreign Application Priority Data
Dec. 30, 2013 (KR) 10-2013-0167818

(51) Int. Cl. H01L 23/00; B22F 3/10; B23K 35/02; B23K 1/00; B23K 35/30

(52) U.S. Cl. CPC H01L 24/27; B23K 1/00; B23K 35/3006; B23K 35/025; B22F 3/10; B22F 3/1003; H01L 2224/27505

(57) ABSTRACT

A method of joining silver paste is provided that includes preparing silver paste including a plurality of silver powders and solid phase sintering medium materials capable of surrounding each silver powder. In addition, the method incldues heating the silver paste at an oxygen partial pressure that is greater than a level at an atmospheric pressure, and joining the silver powders.

### CROSS-REFERENCE TO RELATED APPLICATION

This application claims priority to and the benefit of Korean Patent Application No. 10-2013-0167818 filed in the Korean Intellectual Property Office on Dec. 30, 2013, the entire contents of which are incorporated herein by reference.

### TECHNICAL FIELD

The present invention relates to a method of joining silver paste. More particularly, the present invention provides a method of joining silver paste for joining semiconductor devices.

### BACKGROUND

In accordance with the recent trend of enlargement in size and capacity of application equipment, a demand for semiconductor devices for electric power, having a high breakdown voltage, a high current, and a high-speed switching characteristic has been increased. Among the semiconductor devices, a silicon carbide (SiC) semiconductor device may have a merit. For example,since the silicon carbide semiconductor device has a wider band gap than the conventional silicon (Si) semiconductor device, a semiconductor characteristic may be more stably implemented at high temperatures.

However, a packaging material may additionally need to be stably applied even at elevated temperatures to obtain a substantially high temperature operation effect. Particularly, since a conventional solder used to join the semiconductor devices has a melting temperature of less than about 230° C., the solder may not be used at a junction temperature of about 250° C. or greater at which the silicon carbide semiconductor device may be applied and operated.

Recently, a high temperature solder including gold (Au) and the like has been proposed as an alternative to replace the current solder, but it has been reported that the high temperature solder may be more expensive and may have a reduced characteristic such as junction strength.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention provides a method of joining silver paste without heating to a melting point of silver.

In an exemplary embodiment of the present invention, a method of joining silver paste may include: preparing silver paste that includes a plurality of silver powders and solid phase sintering medium materials which is capable of surrounding each silver powder; heating the silver paste at an oxygen partial pressure that is greater than an atmospheric oxygen partial pressure; and joining the silver powders.

The heating of silver paste may be performed at a temperature of about 250 to about 900° C. The oxygen partial pressure may be greater than 0.21, and equal to or less than about 1. The sintering medium material may be, but not limited to, a glass frit. The heating of silver paste may include converting the solid phase sintering medium material into a liquid phase sintering medium material.

In an exemplary embodiment, the joining of the silver powders may include: contacting the liquid phase sintering medium material surrounding a surface of each silver powder to the adjacent liquid phase sintering medium material; and diffusing silver atoms and silver ions of the silver powder through the liquid phase sintering medium material to form a junction portion which joins the silver powders to each other. In the joining of the silver powders, the liquid phase sintering medium material may be removed.

As described above, according to various exemplary embodiments of the present invention, heating the silver paste may be performed at an oxygen partial pressure that is greater than an atmospheric oxygen partial pressure to join the silver paste.

### BRIEF DESCRIPTION OF THE DRAWINGS

The above and other objects, features and advantages of the present invention will be more clearly understood from the following detailed description taken in conjunction with the accompanying drawing. FIGS. 1 to 4 are views sequentially illustrating a method of joining silver paste according to an exemplary embodiment of the present invention.

FIG. 1 illustrates an exemplary state of silver paste which includes silver powders 100 and solid phase sintering medium materials 200 surrounding the silver powders 100 according to an exemplary embodiment of the present invention;

FIG. 2 illustrates an exemplary state of silver paste in which the silver paste is heated and formed liquid phase sintering medium materials 210 surrounding the silver powder make contact with adjacent liquid phase sintering medium materials 210 surrounding other silver powder according to an exemplary embodiment of the present invention;

FIG. 3 illustrates an exemplary state of silver paste in which a junction portion 110 is formed between silver powders 100 surrounded by the liquid phase sintering medium materials 210 according to an exemplary embodiment of the present invention; and

FIG. 4 illustrates an exemplary state of silver paste in which silver powders 100 are joined through the junction portion while the liquid phase sintering medium materials is completely removed according to an exemplary embodiment of the present invention.

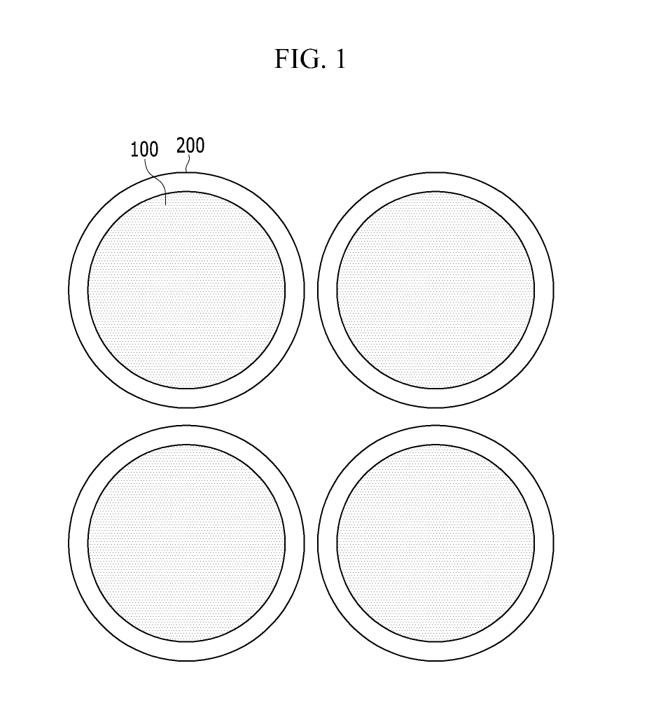

Reference numerals set forth in the FIGS. 1-4 include reference to the following elements as further discussed below:
100: Silver powder
110: Junction portion
200: Solid phase sintering medium material
210: Liquid phase sintering medium material

### DETAILED DESCRIPTION

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

Hereinafter, exemplary embodiments of the present invention will be described in detail with reference to the accompanying drawings. As those skilled in the art would realize, the described embodiments may be modified in various different ways, all without departing from the spirit or scope of the present invention. On the contrary, exemplary embodiments introduced herein are provided to make disclosed contents thorough and complete and sufficiently transfer the spirit of the present invention to those skilled in the art.

In the drawings, the thickness of layers, films, panels, regions, etc., are exaggerated for clarity. It will be understood that when a layer is referred to as being “on” another layer or substrate, it can be directly on the other layer or substrate, or intervening them may also be present. Like reference numerals designate like elements throughout the specification.

According to an exemplary embodiment of the present invention, a silver paste may include a silver powder 100 and a sintering medium material 200, and the sintering medium material 200 may be capable of surrounding a surface of the silver powder 100. In particular, the sintering medium material 200 may be, but not limited to, a glass frit. Silicon carbide (SiC) semiconductor devices may be joined using the silver paste. When the semiconductor devices are joined, the silver paste may be formed on the semiconductor device of a junction target, and the semiconductor devices may be joined by joining the silver paste and the silver paste. Subsequently, when the silver paste and the silver paste are joined, the silicon carbide semiconductor devices may be joined.

Hereafter, a method of joining the silver paste will be described in various exemplary embodiments. FIGS. 1 to 4 sequentially illustrate the method of joining the silver paste according to an exemplary embodiment of the present invention.

In FIG. 1, the silver paste may be prepared. The silver paste may include a silver powder 100 and a sintering medium material 200. The sintering medium material 200 may be a solid phase, and may be capable of surrounding a surface of the silver powder 100. In an exemplary embodiment, a silver powder may be in a form of a particle. A diameter of the silver powder 100 may be in a range of about 1 μm to about 10 μm.

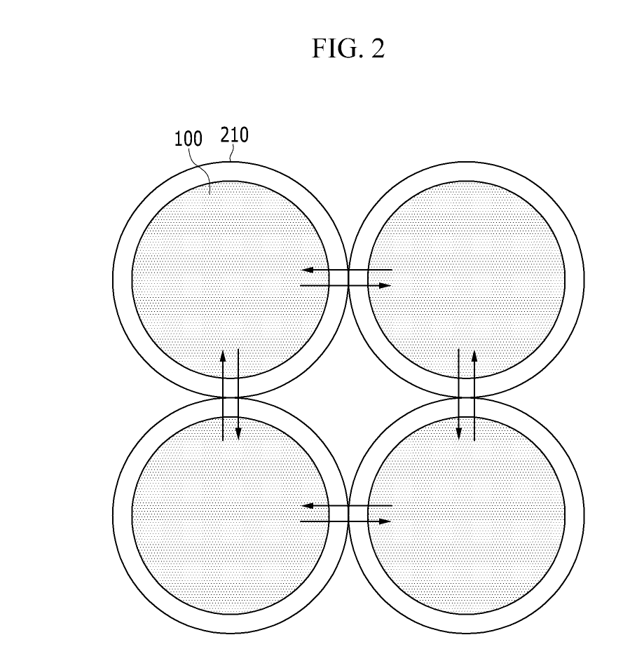

In FIG. 2, the silver paste including silver powders 100 and sintering medium material 210 may be heated. A heating temperature may be in a range of about 250° C. to about 960° C. Heating of the silver paste may be performed at an atmospheric pressure, and may be performed in a state where an oxygen (O₂) partial pressure is greater than the oxygen partial pressure of at an atmosphere. In particular, the oxygen partial pressure may be greater than about 0.21, and equal to or less than about 1. When the silver paste is heated, the solid phase sintering medium material 200 may melt and be converted into a liquid phase sintering medium material 210. Since a melting temperature of silver is about 962° C., a powder state of silver powder 100 may be maintained even though the silver paste is heated. In addition, a chemical reaction may not occur between the liquid phase sintering medium material 210 and the silver powder 100 in a powder state. Subsequently, the liquid phase sintering medium material 210 surrounding the surface of the silver powder 100 may approach each other and contact with the adjacent liquid phase sintering medium material 210, and the liquid phase sintering medium materials 210 surrounding the silver powder 100 may be in direct contact with each other. In addition, silver atoms and silver ions (Ag⁺) of the silver powder 100 may be diffused through the liquid phase sintering medium material 210.

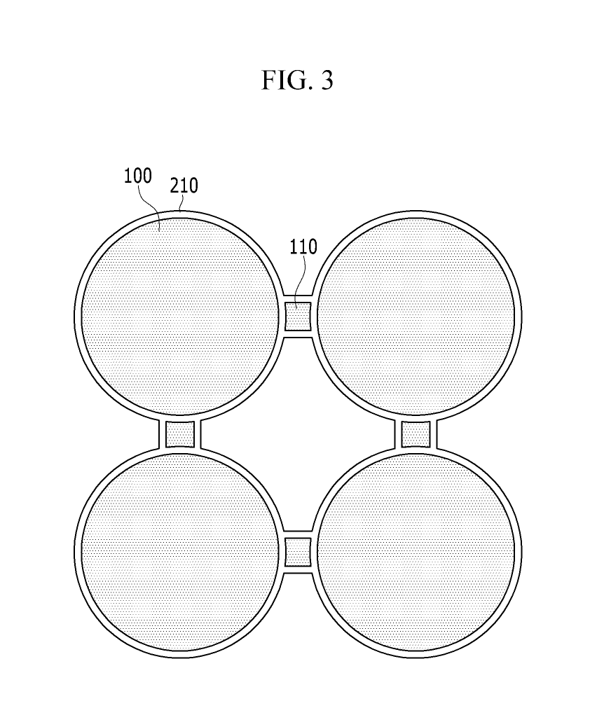

In FIG. 3, as the heating of the silver paste proceeds, diffusion of the silver atoms and the silver ions of the silver powder 100 may be activated to form a junction portion 110 which may join the silver powders 100, and thus the liquid phase sintering medium material 210 may be gradually removed.

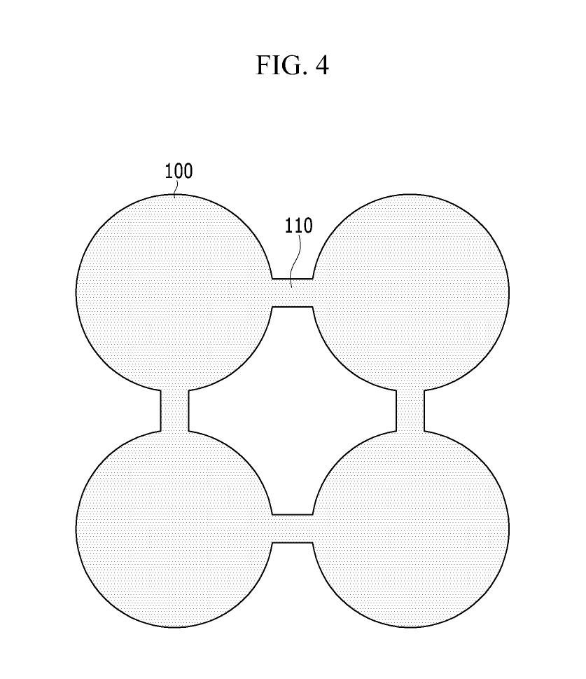

In FIG. 4, the liquid phase sintering medium material 210 surrounding the silver powder 100 may be completely removed, and the silver powders 100 in the silver paste may be joined at least one or more other silver powders through the junction portion 110. Accordingly, the silver paste may be joined and the semiconductor devices on which the silver paste is formed may be joined due to junction of the silver paste.

According to an exemplary embodiment, a junction time may be reduced by performing junction of the silver paste at the oxygen partial pressure that is greater than the atmospheric oxygen partial pressure. Accordingly, when the semiconductor devices are joined, an exposure time of the semiconductor devices to substantially high temperatures may be reduced, thereby minimizing a damage of the semiconductor devices.

In the related arts, junction of the existing silver paste may be performed by sintering, and sintering may rely on a temperature, a sintering time, and particularly on a size of the silver powder. However, according to various exemplary embodiments of the present invention, since heating may be performed in a temperature range of lower than the melting point of silver, the silver powder having substantially large particles may be used.

While this invention has been described in connection with what is presently considered to be various exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of joining silver paste, comprising:
preparing silver paste that icnldues a plurality of silver powders and solid phase sintering medium materials capable of surrounding each silver powder;
heating the silver paste at an oxygen partial pressure that is greater than an atmospheric oxygen partial pressure; and
joining the silver powders.

2. The method of claim 1, wherein the heating of the silver paste is performed at a temperature in a range of about 250° C. to about 900° C.

3. The method of claim 1, wherein the oxygen partial pressure is greater than about 0.21, and equal to or less than about 1.

4. The method of claim 1, wherein the sintering medium material is a glass frit.

5. The method of claim 1, wherein the heating of the silver paste includes:
converting the solid phase sintering medium material into a liquid phase sintering medium material.

6. The method of claim 5, wherein the joining of the silver powders includes:
contacting the liquid phase sintering medium material surrounding a surface of each silver powder to the adjacent liquid phase sintering medium material; and
diffusing silver atoms and silver ions of the silver powder through the liquid phase sintering medium material to form a junction portion which joins the silver powders.

7. The method of claim 6, wherein in the joining of the silver powders, the liquid phase sintering medium material is removed.
